(19) United States
(12) Patent Application Publication
(10) Pub. No.: US 2006/0124349 A1
(43) Pub. Date: Jun. 15, 2006

(54) Diamond-coated silicon and electrode

(76) Inventors: Hiroyuki Fujimura, Tokyo (JP); Roberto Massahiro Serikawa, Kanagawa (JP); Naoki Ishikawa, Gunma (JP); Takahiro Mishima, Hyogo (JP)

Correspondence Address: Robert H Hammer III, Suite I, 3121 Springbank Lane, Charlotte, NC, 28226, US

(21) Appl. No.: 10/540,464

(22) PCT Filed: Dec. 24, 2003
(86) PCT No.: PCT/JP03/16553

§ 371 Date: Jan. 9, 2006

(30) Foreign Application Priority Data
Dec. 25, 2002 (JP) 2002374788

(51) Int. Cl. H05K 1/09

(52) U.S. Cl. 174/256; 174/257

(57) ABSTRACT

The present invention intends to provide an industrially applicable diamond electrode and a diamond-coated silicon used in the electrode. A silicon substrate having a thickness of 500 μm or less, at least partially coated with electrically conductive diamond is used as a diamond-coated silicon. In addition, an electrically conductive support substrate and the diamond-coated silicon is used as an electrode. The diamond-coated silicon is flexible and it can be adhered to the electrically conductive support substrate, and thereby a large area electrode and a three-dimensional electrode structure can be easily obtained.

### TECHNICAL FIELD

The present invention relates to silicon coated with electrically conductive diamond and use of such silicon as an electrode. An electrode according to the present invention can be applied to electrolytic reaction, electrode reaction, sensors and the like.

### BACKGROUND ART

Diamond has the brilliance characteristic that is utilized in gems and ornaments and is known to be one of the hardest substances on the earth, and exhibits excellent physicochemical stability against frictional wear, chemical, pressure and so on. This physicochemical stability is advantageously used in many familiar products such as diamond cutter for glass, drill tool and grinder disk.

Furthermore, carbon of the diamond belongs to the same group IV of silicon. Accordingly, when carbon forms a diamond structure (sp3 crystal system), exhibits semiconductor characteristics similar to silicon, has strong interatomic binding forces, and has a large band gap such as about 5.5 eV at room temperature corresponding to the binding energy of valence electrons. Similarly to silicon, a p-type semiconductor is formed when an element of group III such as boron is used as a dopant, and an n-type semiconductor is formed when an element of group V such as nitrogen or phosphorus is used as a dopant. Accordingly, application researches of diamond electronic devices are under progress (H. Ogushi, FUTURE MATERIAL, 2, No. 10 (2002): 6-13). Although pure diamond is an excellent electrical insulator, diamond is a material whose electrical conductivity can be changed arbitrary from a degree of an insulator to that of metal by controlling the dopant amount.

Unique electrochemical characteristics of diamond are becoming evident in recent years besides the physicochemical and semiconductor characteristics. Diamond was found to exhibit wide thermodynamic window when used as an electrode in an aqueous solution. Oxygen and hydrogen are generated only under a large absolute overvoltage. The hydrogen generating potential is 0 V against the standard hydrogen electrode (SHE) and the oxygen generating potential is +1.2 V from the thermodynamic calculation. Accordingly, the width of the thermodynamic window is 1.2 V. There is a dependency to the electrolyte solution, but the thermodynamic windows are 3.2 to 3.5 V for diamond electrode, about 2.8 V for glassy carbon electrode and 1.6 to 2.2 V for platinum electrode. The wide thermodynamic windows mean that the electrode is inadequate for generating oxygen and hydrogen; however, other reactions can take place at the electrode. When diamond electrode is used for waste water treatment, for example, it is known that efficient removal of a chemical oxygen demand (COD) of the waste water can be achieved (JP-A No. 07-299467). This is attributed to the mechanism in which the OH radicals take part in the mineralization of the COD compound to carbon dioxide and to a large generation of OH radicals on the surface of the diamond electrode (JP-A No. 2000-254650). Processes of sterilizing drinking water and water for pools, cooling towers using a diamond electrode are under development due to this large generation of the OH radicals on the electrode surface.

Furthermore, the low background current (remaining current) in comparison to the other electrodes can be cited as another unique electrochemical characteristics of the diamond. The diamond, due to its low background current and to the wide thermodynamic windows, is expected to be applied to electrode for sensors of low concentrations of metals and ecological materials in aqueous solution.

Chemical vapor deposition (CVD) process is used as the process for manufacturing diamond electrode by coating the substrate with a diamond film. At present two kinds of processes are mainly used: hot-filament CVD process and microwave plasma CVD process. Both methods are processes for synthesizing artificial diamond under reduced pressure, without applying high pressure.

In the microwave plasma CVD process, plasma is generated by irradiating microwave of around 2.4 GHz to vapor of organic compounds; that become the carbon source of diamond; such as methane, acetone and the like in the range of several hundreds ppm to several percents under a hydrogen atmosphere. When the substrate, kept at a temperature in the range of 600 to 1000° C., is placed in the vicinity of generated plasma, a diamond film grows on the substrate. In order to impart electrical conductivity to the diamond film, a p-type semiconductor diamond film is grown when a boron source such as diborane or boron oxide is mingled besides methane gas under a hydrogen atmosphere. By use of the microwave plasma CVD process, mainly silicon wafer substrate is coated with the diamond film and applications such as in sensors are expected to be developed. The adhesion of the diamond film to the silicon substrate is considered to be excellent because silicon and diamond are elements that belong to the same group IV and have similar crystal structures. The diamond film closely adheres to the silicon wafer by a middle layer (interlayer) which is a very thin interlayer of silicon carbide naturally formed when the diamond film grows on silicon. The diamond film generated by the microwave plasma CVD process is known to be relatively stable and high quality (JP-A No. 10-167888).

On the other hand, in the hot-filament CVD process, diamond film grows on a substrate; disposed in the vicinity of a filament which is made of tungsten, tantalum, ruthenium, etc.; when the filament is heated to around 2000° C. under a hydrogen atmosphere containing as a carbon source few percent of at least one kind of hydrocarbons such as methane, ethane, propane, butane and unsaturated hydrocarbons, alcohols such as ethanol or ketones such as acetone. A large area of diamond film can be manufactured by disposing long filaments above this substrate. In the case that a 1-m² substrate is coated, for example, 20 filaments having a length of 1 m with intervals of 5 cm therebetween have only to be disposed above the substrate inserted in a deposition chamber. Similarly to the case of the microwave plasma CVD process, a p-type semiconductor diamond film grows when a boron source is supplied together with methane or the like. The substrate temperature in this case is maintained at about 800° C. Since the hot filament CVD process is capable of coating such large area, coating technology for metal substrates in which there is no restriction on the size is in development (JP-A 09-124395).

### DISCLOSURE OF INVENTION

(Problems that the Invention Intends to Solve)

However, silicon wafer is frequently used as the silicon substrate material for diamond electrode, and its surface area is very small. Precisely speaking, the main size of silicon wafers in the market now is 8 inch (200 mm) in diameter and even the largest one is 300 mm in diameter. Accordingly, there is a limitation in manufacturing a diamond electrode with a large surface area using silicon as the substrate material. Furthermore, when the microwave plasma CVD process is used, diamond film can be formed without difficulties on small substrates of several square centimeters; but, for the case of a large substrate such as one square meter, at present it is extremely difficult to coat the entire surface of the substrate with a diamond film. Precisely speaking, the difficulty for large coating is due to the technical difficulty in generating plasma that can cover the entire surface of such substrate of one-square meter.

Furthermore, the thickness of the silicon wafers is normally about 725 μm or more. Accordingly, when a large area electrode is tried to be prepared by connecting diamond-coated silicon wafers to an electrically conductive support substrate material with a large area, the connection is difficult because the silicon wafer has small flexibility. Additionally, the electrical conductivity of the silicon wafer becomes inevitably low due to its thickness, whereby it is difficult to use as an electrode.

Moreover, diamond having a homo-epitaxial structure can grow in the microwave plasma CVD process, if single crystal diamond is used as a substrate. However, the diamond films formed on the silicon wafers are in most cases polycrystalline diamond films.

On the other hand, as mentioned above, in the hot filament CVD process, coating technology for a metal substrate without size limitation has been developed using tantalum, niobium or tungsten as the metal substrate.

However, the crystal structures of the substrate metals are completely different from an epitaxial structure of the diamond crystal. Accordingly, a strong interlayer(middle layer) that join the metal and the diamond is necessary in order to strongly adhere diamond to the metal substrate. For example, when a niobium metal plate will be coated with diamond, formation of a niobium carbide interlayer is necessary. However, the layer of niobium carbide is not so easily formed like in the case of silicon carbide, accordingly, before formation of the diamond film, a separate coating step of a niobium carbide layer is necessary. The coating conditions of such metal carbide are largely dependent on the pre-treatment of the substrate metal, the coating temperature and the gas composition. Operational conditions are complicated and the influences of respective operational factors on the formed metal carbide are not yet completely understood. Then, there is a problem that, depending on the state of the metal carbide layer, the quality of the coated diamond layer, in particular, the stability (durability) is largely affected. Furthermore, the crystallization process proceeds very slowly even when the film of diamond comes to be formed directly on the layer of metal carbide by means of the hot filament CVD process. Accordingly, usually it is necessary to bury diamond fine powder as seed crystals in the layer of metal carbide.

Furthermore, when a diamond electrode is manufactured using niobium as the substrate, for example, an electrically conductive support substrate with the same shape of the final electrode is prepared and directly coated thereon with a diamond film. Since the coating process is carried out at a high temperature such as 800° C. or more, there is a problem that the electrode cannot be obtained as designed because deformation by thermal effects takes place in the electrically conductive support substrate. The deformation due to the heat becomes more remarkable when the electrode has three-dimensional structure.

Still furthermore, the existing manufacturing method of diamond electrodes is basically a batch process. That means silicon wafers or metal substrates are carried into the CVD unit by lot, and pressure reduction, temperature rising, coating, temperature decreasing, pressure rising are repeated in the CVD unit, with a vast energy loss in the manufacturing method. Accordingly, these problems specially disturb the mass production of diamond electrodes and this is one of reasons why the diamond electrodes are not widely diffused.

The present invention has been made in order to overcome these problems and intends to provide an industrially applicable diamond electrode and a diamond-coated silicon that is used in the diamond electrode.

(Means for Solving the Problems)

The present inventors found that, when electrically conductive diamonds are coated on a silicon substrate with a definite thickness, the foregoing problems can be overcome, and thereby the present invention has been completed.

That is, the first aspect of the invention relates to diamond-coated silicon in which a silicon substrate having a thickness of 500 μm or less is at least partially coated with electrically conductive diamond.

Furthermore, the second aspect of the invention relates to an electrode comprising an electrically conductive support substrate and the diamond-coated silicon.

### BRIEF DESCRIPTION OF THE DRAWINGS

FIGS. 1a and 1b are diagrams showing a structure of a diamond-coated silicon according to the present invention.

FIG. 2 is a diagram showing an electrode according to the invention.

FIG. 3 is a diagram showing an electrode according to the invention.

FIG. 4 is a diagram showing an electrode according to the invention.

### BEST MODE FOR CARRYING OUT THE INVENTION

The silicon substrate that is used in the invention is not particularly restricted as far as it has a thickness of 500 μm or less. For example, silicon substrate obtained by slicing silicon ingot, that is used to prepare silicon wafers, in the thickness of 500 μm or less can be used. However, when the silicon ingot is sliced, cutting portion is wasted; accordingly, it is preferable to use a silicon substrate that is manufactured in the thickness of 500 μm or less by means of a plate-like crystal growth process. Here, the plate-like crystal growth process means a process for obtaining plate-like silicon substrate and is not particularly restricted as far as a silicon substrate having thickness of 500 μm or less can be obtained.

There is no particular lower limit for the thickness of the silicon substrate used in the invention. However, from a viewpoint of handling convenience, thickness of 0.1 μm or more is preferable. That is, the thickness of the silicon substrate to be used in the invention is preferably in the range of 0.1 to 500 μm, more preferably in the range of 10 to 300 μm, and still more preferably in the range of 50 to 200 μm. When the thickness exceeds 500 μm, the electrical resistance becomes higher, resulting in disadvantages when used as an electrode. Furthermore, when the thickness exceeds 500 μm due to the decrease in flexibility fragility increases and the thermal expansion due to generated heat by a high current density is difficult to be absorbed, resulting in being readily cracked.

Furthermore, the silicon substrate used in the invention may be any one of single crystal, polycrystal or amorphous one; however, from the viewpoints of facility in diamond film coating and better adhesiveness, a single crystal is preferably used.

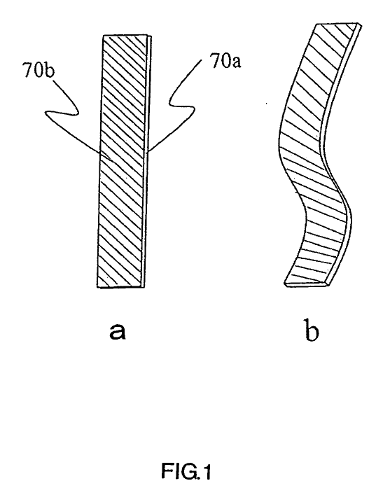

FIGS. 1a and 1b show examples of embodiment of diamond-coated silicon according to the invention. In the diamond-coated silicon, silicon substrate 70a is coated with electrically conductive diamond layer 70b. The example illustrated in FIG. 1a has a diamond-coated silicon with 100 mm in width and 1 m in length, but the width and length can be larger or smaller. Furthermore, as shown in FIG. 1b, the diamond-coated silicon according to the invention is flexible due to the thinner thickness and a large electrode described below can be readily assembled as well.

In the following, electrode according to the invention will be described. An electrode according to the invention is provided with an electrically conductive support substrate and a diamond-coated silicon. The electrically conductive support substrate used in the invention is not particularly limited as far as it has electrical conductivity and can support the diamond-coated silicon. That is, the electrically conductive support substrate supplies electrical current to the diamond formed on the silicon substrate and serves as a mechanical reinforcement for the diamond-coated silicon and thereby prevents the diamond-coated silicon from being damaged. Furthermore, the material and shape of the electrically conductive support substrate can be appropriately selected in accordance with target applications of electrodes, electrolytic reactions, apparatus structures or apparatus designs. Thereby the degree of freedom can be increased in the design of electrode and apparatus.

Examples of electrically conductive support substrate include metals such as titanium, nickel, tantalum, copper, aluminum, niobium and iron; carbon materials such as graphite; and various kinds of alloys such as stainless steel, carbon steel, brass, Inconel, monel and Hastelloy. Noble metals such as platinum, iridium, ruthenium, gold and silver plated on the above metals, carbon materials and alloys; as well as metals, carbon materials or alloys coated with oxide of the noble metals or noble metal mixtures by sintering process may also be used. The electrically conductive support substrate is preferably surface-treated or cleaned by pretreatment depending on the kind of the support substrate. When titanium is used as the electrically conductive support substrate, for example, the surface of titanium is preferably roughened in advance with acid, alkali or blasting. It is preferable that the support substrate is subjected to the surface-treatment, thereafter cleaned with pure water and then subjected to the subsequent process of welding, adhesion with diamond-coated silicon. The back face of the diamond-coated silicon, in which the electrically conductive support substrate will be welded or adhered, that is, the face of the silicon substrate in which the diamond layer is not coated is also preferably surface-treated in advance. The back face of the diamond-coated silicon may also be roughened with sandpaper or grinder made of silicon carbide. The adhesiveness and/or the electric conductivity between the diamond-coated silicon and the electrically conductive support substrate are improved by applying these surface treatments.

Welding or adhesion of the diamond-coated silicon and the electrically conductive support substrate can be carried out by various kinds of processes. Metal with low melting point such as copper, aluminum, indium or respective alloys may be used for soldering. Other stronger adhesion or welding process such as hot isostatic pressing (HIP) or thermal diffusion bonding may also be applied in place of soldering. Welding can also be carried out by dissolving powder of gold, platinum or silver in an organic solvent such as cyclohexane, and then applying the resulting mixture on the electrically conductive support substrate or the back face of diamond-coated silicon by means of printing method, and thereafter sintering at temperature in the range of 400 to 600° C. under a reducing atmosphere. Furthermore, welding of the diamond-coated silicon and the electrically conductive support substrate may be carried out by similarly applying paste of gold, platinum, silver or copper by the printing method, and thereafter sintering at a temperature in the range of 100 to 1000° C. under a reducing atmosphere. Still furthermore, the electrically conductive support substrate and the diamond-coated silicon may be adhered at a lower temperature using electrically conductive epoxy resin that contains gold, platinum, silver or copper. More simple process of adhesion may be carried out by using electrically conductive tapes of carbon, copper with a double adhesive face. The low melting point metals or alloys such as copper, aluminum or indium; the electrically conductive epoxy resins containing gold, platinum, silver or copper; and the electrically conductive tapes of carbon, copper with double adhesive face constitute an electrically conductive bonding material to be used in the invention.

The electrically conductive support substrate and the diamond-coated silicon are not necessarily adhered or welded over the entire surface. They are preferably adhered or welded at least in one place. They may be locally adhered in a point, or in lines with appropriate width and interval. Furthermore, at least one face of the electrically conductive support substrate may be adhered or welded to the diamond-coated silicon.

Since the diamond-coated silicon to be used in the electrode according to the invention is flexible, it can be adhered, for example, to electrically conductive support substrate with a cylindrical shape forming a three-dimensional electrode structure. Furthermore, an electrode according to the invention can be used not only for a large area electrode described below but also in a small electrode for use in a sensor, for example. When the small electrode is manufactured, an electrochemical sensor with a 1 mm square and 100 μm thick electrode, for instance, may be easily manufactured by cutting the diamond-coated silicon with a diamond cutter and then bonding the cut diamond-coated silicon to the electrically conductive support substrate.

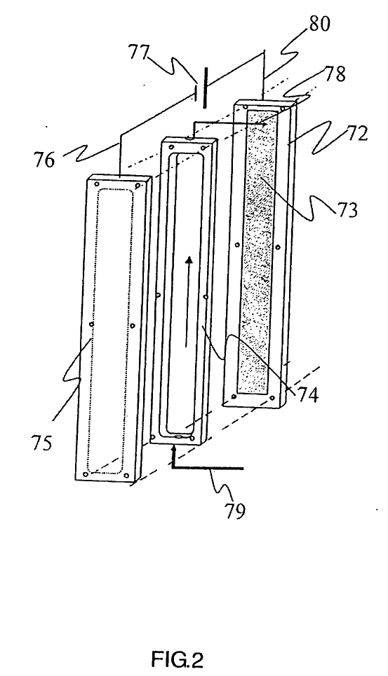

In FIG. 2, an example of an electrode according to the invention is shown. FIG. 2 shows an example of electrode that can be used to sterilize water. In this example, the electrode is composed of an electrically conductive support substrate 72 adhered or welded to the diamond-coated silicon 73; a gasket 74 made of an insulating material; and an electrode 75 that works as the counter-electrode. In this example, the electrolytic cell forms a filter press type by fixing them with screw. Here, the diamond-coated silicon works as an anode and the gasket 74 works also as a spacer against the counter electrode. The counter electrode, working as a cathode, may be constructed from the same diamond-coated silicon and the electrically conductive support substrate, or may be constructed by some materials having lower corrosion resistance such as stainless steel or titanium plate. The gasket 74 is provided with a hollow portion, and water to be processed, which is inserted from a line 79, flows through the hollow portion in upflow mode, and is drained from a line 78 together with hydrogen generated at the cathode. On the surface of the diamond film, OH radicals are generated or chloride ions contained in the water to be processed are converted to hypochlorous acid, and the water to be processed is sterilized due to these OH radicals or hypochlorous acid. The width and length of the hollow portion of the gasket 74 are preferably set to about 5 to 40 mm smaller than the width of the diamond-coated silicon. With this configuration, the electrically conductive support substrate does not come into direct contact with the water to be processed. The electrically conductive support substrate may be corroded when the water to be processed and the electrically conductive support substrate come into contact. As the material of the gasket 74, various kinds of rubbers such as silicone rubber and natural rubber or relatively soft plastics such as Teflon (registered trade name) and soft vinyl chloride can be used, and a fluorinated rubber is preferably used. The distance between electrodes is not particularly limited, but from a practical viewpoint, in the range of 1 to 40 mm.

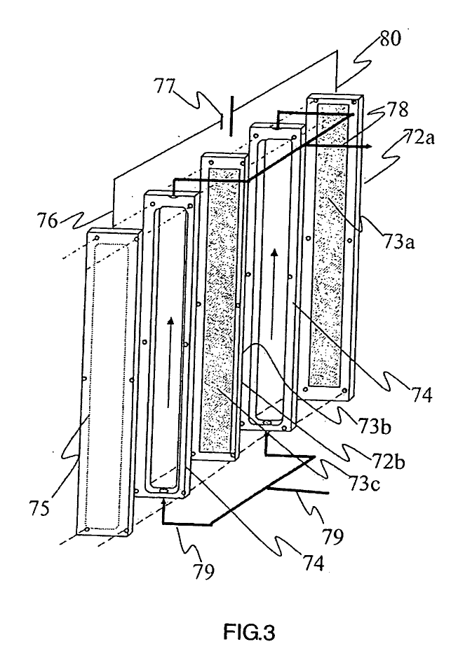

FIG. 3 shows an example where an electrode according to the invention is used as a bipolar electrode (sub-electrode) in the electrolytic cell. The bipolar type electrolytic cell can cope with an increase in the amount of water to be processed by increasing the number of the electrodes and the gaskets. FIG. 3 shows a two-partition bipolar type electrolytic cell in which the diamond-coated silicon 73b and 73c are adhered on both faces of the electrically conductive support substrate 72b, which is disposed at the center of the electrolytic cell. Other configurations are the same as in FIG. 2. When the diamond-coated silicon are stuck on both surfaces of the electrically conductive support substrate, the diamond-coated silicon 73b will work as the cathode and the diamond-coated silicon 73c will work as the anode. Thus, by use of the electrode according to the invention, a bipolar type electrolytic cell can be readily manufactured and thereby a compact electrode can be provided. A divided type electrolytic cell can also be manufactured by interposing an ion-exchange material between the electrodes illustrated in FIGS. 2 and 3.

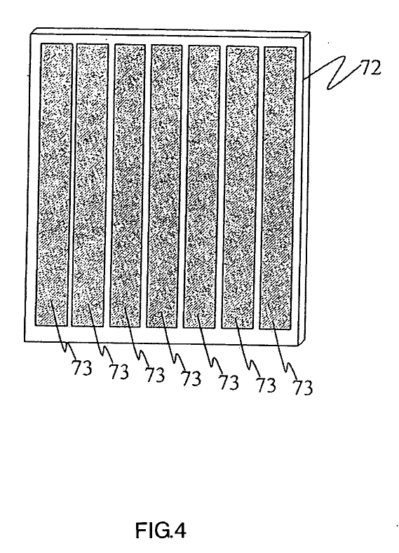

FIG. 4 shows an example of an electrode where several diamond-coated silicon 73 are stuck on a single plate of an electrically conductive support substrate 72. Thereby, with the diamond-coated silicon according to the invention, a wider electrode can be manufactured as well. The diamond-coated silicon 73 and the electrically conductive support substrate 72 are welded by means of the sintering or the like mentioned above. Here, the electrically conductive support substrate 72 is exposed in the parts where the diamond-coated silicon 73 are not stuck, that is, in the periphery parts of the electrodes or between the diamond-coated silicon 73 and the diamond-coated silicon 73. In this case, the exposed part is preferably covered or filled with a corrosion-resistant plastic polymer or the like. As a covering material or a filling agent, various kinds of plastic polymers can be used; however, a fluorinated resin can be preferably used. Hereinafter, an example of a process in which the exposed part of the electrically conductive support substrate is covered with fluorinated resin will be described, but the invention is not limited to this process and other processes may be used. A melting bath, in which the electrically conductive support substrate shown in FIG. 4 can be inserted, is prepared and then a fluorinated resin is inserted in the melting bath and then heated to a temperature in the range of 250 to 450° C. The melting point of the fluorinated resin is different depending on the kind of resin; however, the fluorinated resin melts and liquefies at a prescribed temperature. In the bath where the fluorinated resin is liquefied, the electrically conductive support substrate 72 on which the diamond-coated silicon 73 are stuck is inserted to apply the dip brazing. When the diamond-coated silicon 73 are stuck only in one face of the electrically conductive support substrate 72 and the back surface thereof has not to be coated with the fluorinated resin, the masking with a thin metal such as an aluminum foil or a copper foil can be preferably applied. The entire surface of the electrically conductive support substrate 72 taken out from the melt bath is covered with the fluorinated resin. The electrically conductive support substrate 72 is excellent in the adhesiveness with the fluorinated resin because it has been surface treated by blasting or the like. In contrast, the portion of the diamond-coated silicon 73 is weak in the adhesiveness due to the characteristics of a crystal structure of diamond, and the fluorinated resin can be easily peeled off. When the covering fluorinated resin is cut out with a cutter knife or the like along a little bit inside of the diamond-coated silicon 73, only the fluorinated resin coating of the diamond-coated portion will be peeled off. Thus, an electrode in which only the surface of the diamond-coated silicon portion is exposed and the other parts of the electrically conductive support substrate are inert to the electrolytic reaction can be manufactured. Thereby, a large area electrode that takes advantage of the characteristics of diamond can be manufactured cheaply and efficiently.

(Advantage of the Invention)

By use of diamond-coated silicon according to the invention, a large area electrode or a three-dimensionally structured electrode can be obtained.

1. A diamond-coated silicon comprising a silicon substrate having a thickness of 500 μm or less coated at least partially with electrically conductive diamond.

2. An electrode, comprising an electrically conductive support substrate and the diamond-coated silicon according to claim 1.

3. The electrode according to claim 2, wherein at least one portion of the electrically conductive support substrate is bonded to the diamond-coated silicon.

4. The electrode according to claim 2, wherein at least one surface of the electrically conductive support substrate is bonded to the diamond-coated silicon.

5. The electrode according to claim 3, wherein the electrically conductive support substrate is bonded to the diamond-coated silicon with an electrically conductive bonding material.

6. The electrode according to claim 3, wherein the bonding is performed by welding or adhesion.

7. The electrode according to claim 4, wherein the electrically conductive support substrate is bonded to the diamond-coated silicon with an electrically conductive bonding material.

8. The electrode according to claim 4, wherein the bonding is performed by welding or adhesion.

9. The electrode according to claim 5, wherein the bonding is performed by welding or adhesion.
